(19) United States
(12) Patent Application Publication
(10) Pub. No.: US 2008/0123706 A1
(43) Pub. Date: May 29, 2008

(54) Constant Current Type Power Supplies

(76) Inventors: Alexander Zak, Ashkelon (IL); Richard Olinsky, Kiblutz Givat Brenner (IL); Dov Cohen, Rishon-LeZion (IL); Gabriela Cohn, Rishon-LeZion (IL)

Correspondence Address: Martin D. Moynihan;PRTSI, P.O.Box 16446, Arlington, VA, 22215, US

(21) Appl. No.: 10/586,044

(22) PCT Filed: Jan. 4, 2005
(86) PCT No.: PCT/IL05/00010

§ 371 Date: Sep. 10, 2007

Related U.S. Application Data
(60) Provisional application No. 60/536,523, filed on Jan. 15, 2004.

(51) Int. Cl. H01S 5/068; G05F 3/02; H02J 7/00; H01S 5/40

(52) U.S. Cl. 372/38.04; 323/312; 320/166

(57) ABSTRACT

Constant current power supply arrangements can charge a capacitor with a constant current and are suitable as power supplies for laser diodes. A power supply for a laser diode comprises: a variable voltage power supply, a load path for carrying a laser diode, a shunt path connected in parallel with the load path, a current draining element for switching the shunt path, the current draining element being associated via a first feedback element with the variable voltage power supply such that current drained by the current draining element provides first feedback control of a voltage level of the variable voltage power supply, and a voltage operated second feedback element associated with both the load path and the shunt path to provide second feedback control of the current draining element to drain current via the current draining element in response to current changes at the load. A circuit arrangement for charging a capacitance comprises a load capacitance to be charged, a serially connected inductive component contributing to a serial frequency dependent impedance, and a variable frequency source for supplying charging current at a variable frequency, the variable frequency source being controllable to reduce frequency during charging of the capacitor, thereby to reduce the frequency dependent impedance and maintain a constant level of charging current to the load capacitance.

### FIELD AND BACKGROUND OF THE INVENTION

The present invention relates to constant current type power supplies and, more particularly, but not exclusively to power supplies having rapid stabilization so as to be suitable for use with a laser diode.

With the maturity and growth of fiber optic communication systems, optical memory devices, and medical applications, laser diodes are now relatively common active devices. In fiber optic communication systems, laser diodes are used as signal transmission components that transmit multi-megabit/second digital data, by being turned ON and OFF at very high data rates to generate the required optical representation of the electrical signal inputs to be conveyed over a fiber optic highway to a repeater or receiver station. Laser diodes are greatly preferred over light emitting diodes in these communications systems because of their ability to operate at single defined light frequencies enabling high rate data transmission.

Laser diodes are typically powered by DC current, and are particularly subject to degradation and failure in the event of over current surges and spikes. Indeed laser diodes can suffer damage from surges and spikes which are of mere microsecond duration. Laser diodes are very much current type devices and require supply from as close as possible an approximation to ideal current sources in order to work effectively and not be degraded.

Consequently, laser diodes have to be provided with power supplies that include very robust and rapid over current protection. The over current protection is bulky, and adds weight and expense to the system.

U.S. Pat. No. 5,199,039 discloses a laser diode power supply that uses alight sensitive diode to sense power level changes in the laser diode. The sensed power level changes are used to switch a transistor which is connected to the output of the laser diode, thereby to control the current flowing through the laser diode.

U.S. patent application Ser. No. 10/015103, published as 2002/0114365A1, discloses automatic power control for a laser transmitter having a laser diode.

Another need for a robust current source is circuits with capacitance loads. A capacitor charged by a constant voltage draws relatively large current at the start of charge, and then the current steadily decays as the device approaches full charge. Consequently, using a limited constant current source will result in a long period of time to charge the capacitor to full capacity.

In accordance with Ohm's Law, the current supplied to a load is

$$\frac{V ( i ) - V ( o )}{Z} = Current ,$$

and if the current is to remain a constant the ratio of V(i) less V(o) over Z must remain constant. The voltage at the capacitor is given by

$${V}_{o} ( t ) = ( \frac{I}{C} ) . \times t$$

where C is the capacitance.

It will be appreciated that the voltage across the capacitor is the integral of the current charging the capacitor over time.

As dictated by the equation there are two possibilities for charging a capacitor with constant current. One is to increase the supply voltage during the course of charging. This would require relatively high voltages towards the end of the charge. The other possibility is to reduce the impedance of the circuit during the course of charging, but there is not presently any recognized way of doing this.

There is thus a widely recognized need for, and it would be highly advantageous to have, an improved constant current power supply system devoid of the above limitations.

### SUMMARY OF THE INVENTION

According to one aspect of the present invention there is provided a high speed power supply arrangement suitable for laser diodes, comprising:

a) a variable voltage power supply,

b) a load path for carrying a laser diode,

c) a shunt path connected in parallel with said load path,

d) a current draining element for switching said shunt path, said current draining element being associated via a first feedback element with said variable voltage power supply such that current drained by said current draining element provides first feedback control of a voltage level of said variable voltage power supply, and

c) a voltage operated second feedback element associated with both said load path and said shunt path to provide second feedback control of said current draining element to drain current via said current draining element in response to current changes at said load.

Preferably, said first feedback control is relatively slow and said second feedback control is relatively fast.

Preferably, said first feedback control is set with a response rate suitable for a DC-DC voltage level converter.

Preferably, said second feedback control is set with a response rate in the microsecond order of magnitude.

Preferably, said current draining element is a transistor.

According to a second aspect of the present invention there is provided a method of current regulation to provide constant current to a load comprising:

providing a power source having a controllable output voltage level, providing current to said load from said voltage power source,

connecting a current draining element in parallel with said load, and arranging:

relatively fast feedback control from said load to operate said current draining element to drain over current from said load, and

relatively slow feedback control responsive to current drained by said current draining element to control said output voltage level of said power source.

According to a third aspect of the present invention there is provided a circuit arrangement for charging a capacitance comprising:

a load capacitance to be charged,

a serially connected inductive component contributing to a serial frequency dependent impedance, and

a variable frequency source for supplying charging current at a variable frequency,

said variable frequency source being controllable to reduce frequency during charging of said capacitor, thereby to reduce said frequency dependent impedance and maintain a level of charging current to said load capacitance.

Preferably, a serially connected capacitive component is also used to contribute to said serial frequency dependent impedance.

The circuit may further comprise a current measurement device for measuring said charging current and using said measurement to provide a feedback signal to said variable frequency source, thereby to control said variable frequency to reduce said frequency.

Preferably, said variable frequency source comprises pulse width modulation.

Preferably, said load capacitance is connected to said serial component via a rectifying bridge.

Preferably, said feedback signal is modified to stabilize said charging current at a constant level whilst said load capacitance is charging.

According to a fourth aspect of the present invention there is provided a method of providing constant current charging of a capacitive load comprising:

arranging said capacitive load in series with a reactive impedance comprising at least an inductive element,

providing current at a controllable supply frequency,

measuring an actual charging current of said capacitive load,

using measured changes in said charging current to control said frequency thereby to adjust said reactive impedance so as to keep said charging current substantially constant.

Preferably, said reactive impedance further comprises a capacitive element in series with said inductive element.

The method may further comprise arranging said capacitive load with a rectifying bridge so that said capacitive load receives substantially DC charging current irrespective of said supply frequency. Unless otherwise defined, all technical and scientific terms used herein have the same meaning as commonly understood by one of ordinary skill in the art to which this invention belongs. The materials, methods, and examples provided herein are illustrative only and not intended to be limiting.

### BRIEF DESCRIPTION OF THE DRAWINGS

The invention is herein described, by way of example only, with reference to the accompanying drawings. With specific reference now to the drawings in detail, it is stressed that the particulars shown are by way of example and for purposes of illustrative discussion of the preferred embodiments of the present invention only, and are presented in the cause of providing what is believed to be the most useful and readily understood description of the principles and conceptual aspects of the invention. In this regard, no attempt is made to show structural details of the invention in more detail than is necessary for a fundamental understanding of the invention, the description taken with the drawings making apparent to those skilled in the art how the several forms of the invention may be embodied in practice.

In the drawings:

FIG. 1 is a graph showing the voltage-current characteristic of a laser diode;

FIG. 2A is a simplified conceptual diagram showing an idealized laser diode power supply;

FIG. 2B is a simplified diagram illustrating a high impedance current source of a kind used conventionally in supplying power to laser diodes;

FIG. 3 is a theoretical diagram of a laser diode power supply according to a first preferred embodiment of the present invention;

FIG. 4A is a circuit diagram illustrating one possible practical implementation of the theoretical circuit of FIG. 3;

FIG. 4B is a flow chart illustrating the double feedback control operation of the circuit of FIG. 4A;

FIG. 5 is a simplified circuit diagram illustrating a conventional relatively slow capacitor charging circuit;

FIG. 6 is a simplified circuit showing an inductor as an example of an impedance which can change with a change in frequency;

FIG. 7 is a simplified circuit showing a network of serial capacitive and inductive components the impedance of which can be altered with a change in frequency;

FIG. 8 is a simplified circuit diagram illustrating constant current charging of the load capacitor using the serial network of FIG. 7;

FIG. 9 is a simplified flow chart illustrating an operating procedure for the circuit of FIG. 8 to charge a capacitor, and

FIG. 10 is a graph illustrating impedance against frequency characteristics for circuits according to the present embodiments.

### DESCRIPTION OF THE PREFERRED EMBODIMENTS

The present embodiments comprise power supply arrangements that operate as constant current sources. A first embodiment uses two serial control loops. The power supply is a variable voltage source. The voltage level at the voltage source is controlled by a first control element, which is connected to a shunt branch that serves as a current drain to sink excess current from the load. The second control element senses the current to the load and uses it to change therein the current drain in the shunt branch. The first control element has a fast reaction time whereas the element that controls the voltage source directly is slower, in keeping with the slower reaction time constant of the voltage source. Thus the shunt branch is able to rapidly sink over currents in the time interval before the voltage source has a chance to react, and the voltage source is controlled in a stable manner from the second feedback element. A variable voltage source according to the above embodiment is able to supply currents at the levels needed by laser diodes, in the range between ten to more than one hundred amperes, and yet is able to react to over current spikes within a microseconds.

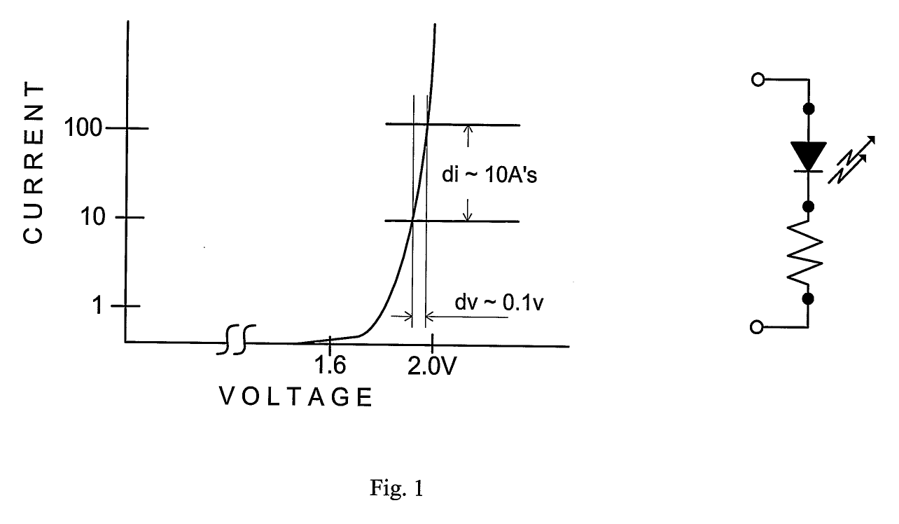

In this context, reference is now made to FIG. 1, which is a simplified voltage-current characteristic of a laser diode. It may be noted that the laser diode load acts as a current sink with an offset bias. As a current sink its dynamic impedance is very small and it results in a circuit for which regulated voltage would be not be suitable to achieve current control.

A second embodiment of the constant current power supply uses feedback from a charging current being supplied to a capacitive load, to alter a supply frequency. The change in supply frequency leads to a change in reactive impedance in the circuit, so that the capacitive load continues to receive constant current over substantially all of the charging period.

The principles and operation of a constant current power supply according to the present invention may be better understood with reference to the drawings and accompanying description.

Before explaining at least one embodiment of the invention in detail, it is to be understood that the invention is not limited in its application to the details of construction and the arrangement of the components set forth in the following description or illustrated in the drawings. The invention is capable of other embodiments or of being practiced or carried out in various ways. Also, it is to be understood that the phraseology and terminology employed herein is for the purpose of description and should not be regarded as limiting.

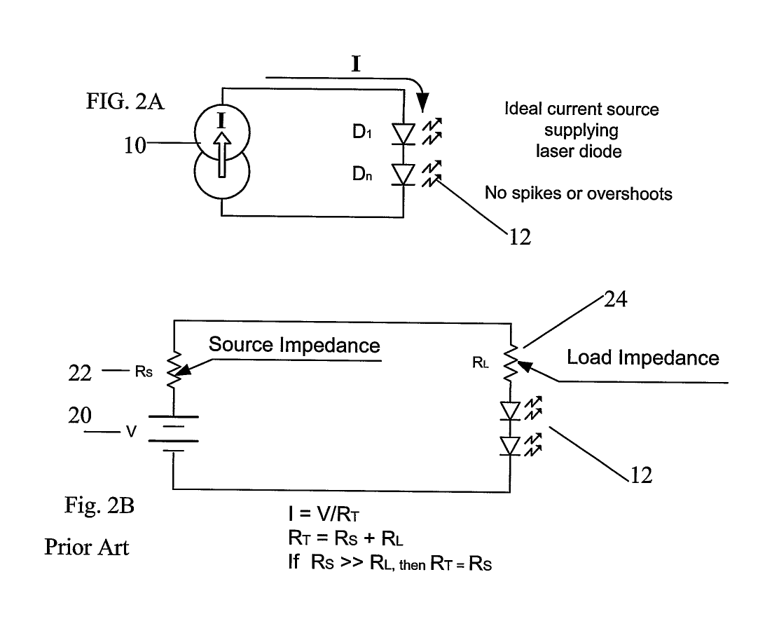

Reference is now made to FIG. 2A, which illustrates an ideal power supply for a laser diode. An ideal constant current source 10 provides a fixed current I to laser diodes D1 to Dn 12 connected in series. The ideal constant current source provides exactly the same current no matter what the conditions in the circuit, and such an ideal source of course does not exist, although it can be approximated. Laser diodes require constant current without overshoot or spikes, and two laser diodes connected in series, as shown in FIG. 1, may typically require current levels of up to 60 amps. As mentioned above, over current spikes of as little as a microsecond's duration are able to cause laser diodes to degrade or even fail.

Reference is now made to FIG. 2B, which is a simplified diagram illustrating a commonly used approximation of a constant current source. The approximation comprises a standard voltage source 20 together with high source impedance 22. The circuit itself includes the laser diodes 12 and load impedance 24. It is appreciated that the load impedance 24 is not intended to designate any circuit component in particular but rather is the sum of the serial impedance in the circuit. The source impedance 22 is high in relation to the load impedance 24, so that changes occurring in the circuit are effectively cancelled out by the source impedance and very little effect is felt on the current.

The disadvantage of the circuit of FIG. 2 is that the source impedance is a series element that dissipates relatively large amounts of power in its own right. The result is both that the power supply has to be large enough to allow the power to dissipate safely and that the power is wasted. The skilled person will appreciate that driving a current of the order of 60A through a large resistor is a very wasteful exercise. Furthermore, the arrangement does not deal sufficiently effectively with surges and spikes.

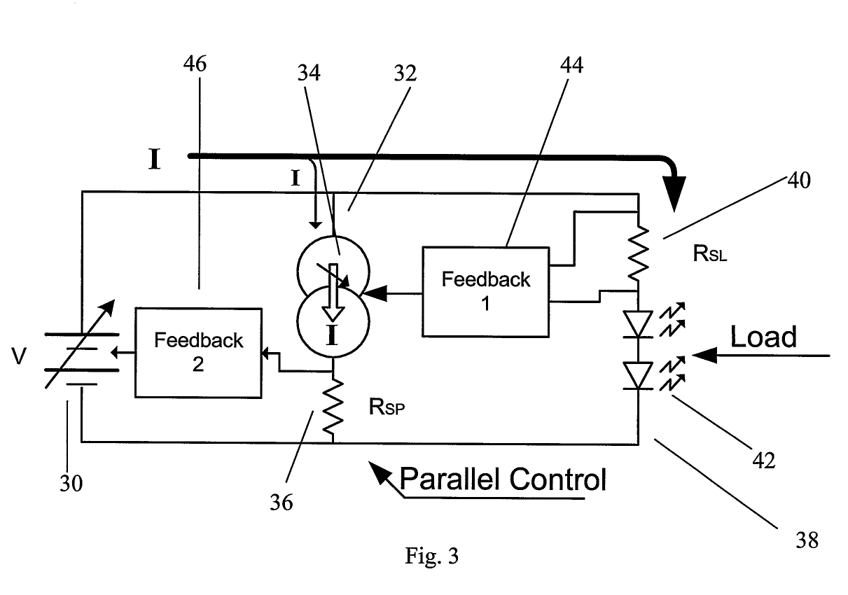

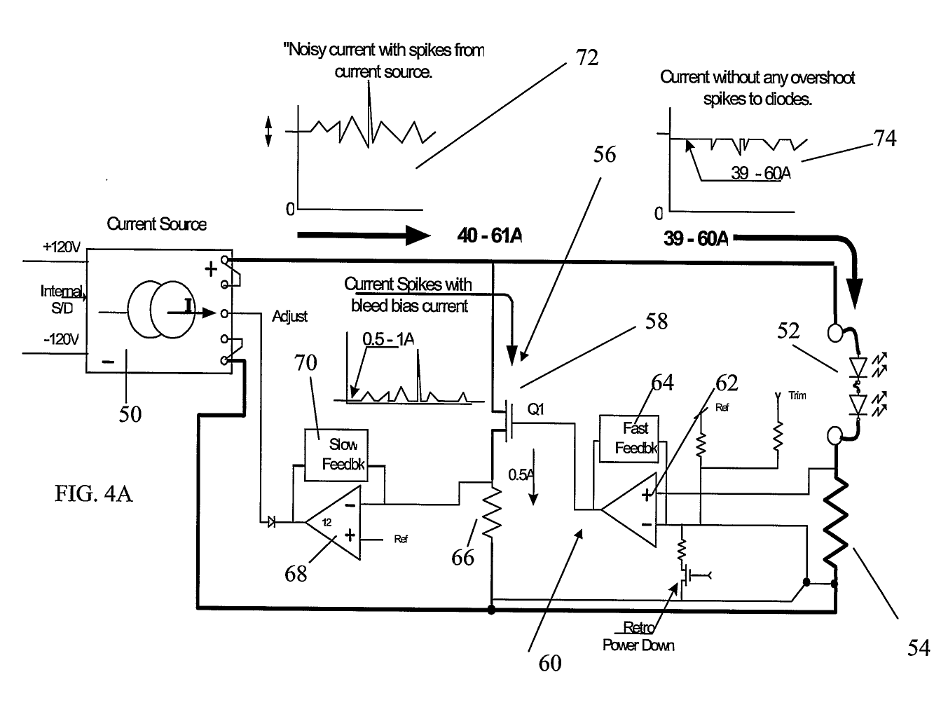

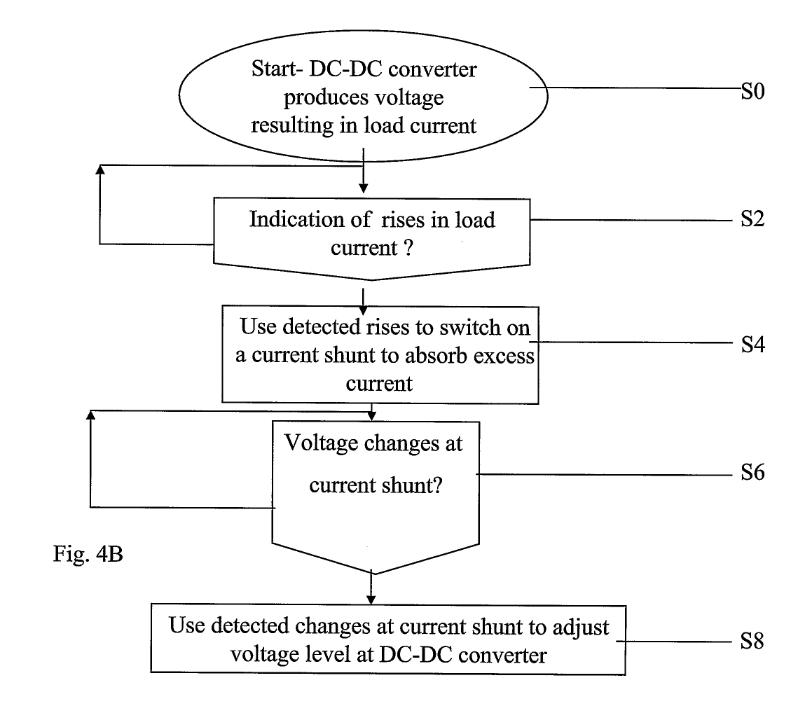

U.S. Pat. No. 5,604,757 describes a laser diode driver circuit which includes active current and power regulation. The circuit is detailed in FIG. 4. Active current regulation is another way of regulating the current and provides an effective current source. However the best regulation of the current source can only be as fast as the voltage source itself can react. Voltage sources cannot react in the microsecond time frame and therefore microsecond over current spikes cannot be prevented by conventional active control. Reference is now made to FIG. 3, which is a theoretical circuit diagram illustrating a first preferred embodiment of the present invention. A voltage source 30 is connected in parallel with first or drain branch 32 comprising a current controlled sink element 34 and sense resistance 36, and also in parallel with a load branch 38 including load sense resistance 40 and the laser diodes 42. First and second feedback elements 44 and 46 are provided between the respective parallel branches.

In operation, a spike or over current event appears as an increased voltage at load sense resistance 40. First feedback element 44 picks up the voltage increase and turns up the current sink control element 34 to drain current down drain branch 32 in parallel to load branch 38. The increased current passing through drain branch 32 causes a voltage change to be experienced at the input to resistance sense element 36. The voltage change is detected at feedback element 46 and used to control the output voltage level at voltage source 30. The first feedback loop, which involves first feedback element 44 and current control element 34, is a very rapid feedback loop, providing the opportunity for microsecond reactions to spikes. The second feedback loop is slower and modifies the supply voltage which is relatively slow to respond. That is to say it would not be effective to connect the fast first feedback loop directly to the voltage source because it could not respond fast enough in any case. The end result is a power supply current source unit that closely approximates a true ideal current source.

Reference is now made to FIG. 4A, which is a simplified diagram illustrating a preferred way of implementing the circuit of FIG. 3. In FIG. 4, a high frequency DC-DC voltage converter 50 is used to develop current for the diodes. The frequency of the device is typically of the order of a megahertz, but the converter itself is unable to prevent line and load originated disturbances. The disturbances, which include spikes and overshoot currents still occur, but are prevented from effectively reaching the diodes by the current sink control loop arrangement as described above. Diodes 52 and load current sense resistance 54 provide one feedback branch of the circuit. A shunt branch 56 comprises a FET 58 which is switched by fast feedback control 60 to drain current away as necessary. Fast feedback control 60 feeds the voltage across the load sense resistance 54 to differential amplifier 62. Differential amplifier 62 has a fast feedback element 64 allowing it to transfer a rapid feedback signal from its outputs to its inputs in a microsecond or less, and the output of the differential amplifier provides controls the FET 58. Thus rises in voltage at load resistance 54 lead immediately to opening of shunt branch 56 so that current can be drained away.

However, when FET 58 is sinks high current, increased voltage appears across series resistance 66 and this voltage in turn is fed to differential amplifier 68. Differential amplifier 68 is connected with relatively slow feedback element 70 and the output of differential amplifier 68 is fed to the DC-DC converter 50. The relatively slow feedback element 70 is preferably given a response time which is commensurate with that of the DC-DC converter.

The current that comes out of the DC-DC converter could be polluted, as shown in first graph 72. However the current following the shunt branch is limited and regulated to a very high standard and is suitable for the laser diodes 52, as shown in second graph 74.

Reference is now made to FIG. 4B which is a simplified flow chart illustrating the double control loop operation of the circuit of FIG. 4A. In FIG. 4B a load such as a laser diode is provided with a current-stage S0. In a subsequent stage S2 an indication of the actual supply current is taken. Typically the indication is taken by measuring the voltage across a load sense resistance. In the event of detection of an over current event the parallel shunt path is driven higher, stage S4, to drain away the excess current. In any event, measurement of the actual supply current or an indication thereof continues.

In a stage S6, voltage changes in the shunt path are measured, and used in a feedback signal to adjust the voltage at the power supply in a stage S8.

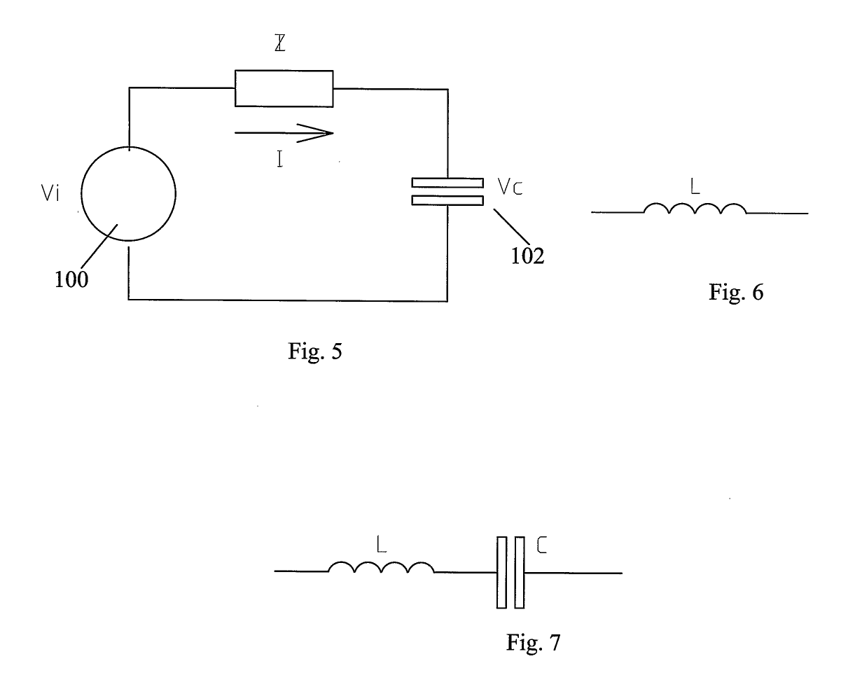

Reference is now made to FIG. 5, which is a simplified diagram illustrating a conventional circuit for charging a capacitor. A standard voltage source 100 provides a voltage Vi to the circuit which includes a capacitor 102. Capacitor 102 charges under the constant voltage, taking a rapid current at first, but the current rapidly decays so that a significant delay occurs before the capacitor is fully charged.

As explained in the background, the current supplied to a capacitor is

$$\frac{V ( i ) - V ( o )}{Z}$$

which must be held constant if the current is to actually remain a constant. Such cannot happen in the circuit of FIG. 5 since the voltage across the capacitor falls as the capacitor is charged. The voltage at the capacitor is given by

$${V}_{o} ( t ) = ( \frac{I}{C} ) . \times t$$

where C is the capacitance.

As previously noted there are two possibilities for charging a capacitor with constant current. One is to increase the supply voltage during the course of charging, but relatively high voltages may be required towards the end of the process. The other possibility is to reduce the impedance of the circuit during the course of charging, and there are two ways in which this can be done. Both methods involve making changes to the frequency at which the current is supplied, since the impedance changes with the frequency. The first method involves providing a series inductance L, such as that shown in FIG. 6. Then an overall impedance Z(t) can be affected by a change in frequency f(t) since Z(t)=2πLf(t). The second method comprises applying both a series inductance L and a series capacitance C, as shown in FIG. 7, so that the effect of a change in frequency on the overall impedance is given by

$$Z ( t ) = 2 π Lf ( t ) - \frac{1}{2 π Cf ( t )}$$

It will be apparent that in the circuit of FIG. 7, a smaller change in frequency leads to a larger change in impedance than in the case in FIG. 6.

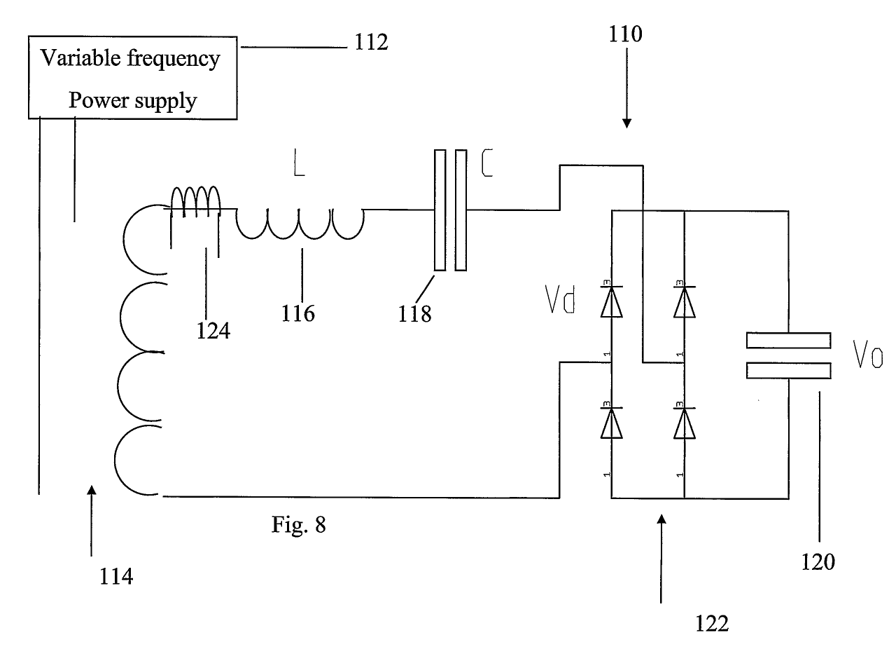

Reference is now made to FIG. 8, which is a simplified circuit diagram for providing constant current charging of a capacitor. Circuit 110 is supplied with current at a frequency set by signal generator 112 which provides a variable frequency signal, preferably using pulse width modulation (PWM). PWM is advantageous since it gives a rectangular signal having a straightforward relationship between the peak amplitude and the root mean square (r.m.s.) amplitude. The signal generator is coupled via coupling inductance 114 to the circuit 110.

Serially connected inductor L 116 and serially connected capacitor C 118 provide the elements detailed in FIG. 7 for adjusting the impedance. Capacitor 120 is the load capacitor that it is desired to charge as quickly as possible and the load capacitor is connected via a rectifying diode bridge 122 so that it receives a DC current despite the PWM frequency modulation, it being appreciated that an AC current is not practical for charging a capacitor. Despite being DC connected, load capacitor 120 still sees the AC impedance of the serially connected components 116 and 118.

Signal generator 112 is controlled by a signal derived from the current level at circuit 110. The current level may for example be measured by inductive pick up element 124. Alternatively, any other current measuring element may be used; i.e. sense resistor or Hall Effect device. The measured current is used in a feedback loop so that as the current falls under influence of the capacitor charging, the frequency f(t) is lowered so that the impedance of the serial components falls. The feedback loop is regulated so that the fall in impedance is sufficient to keep the current constant.

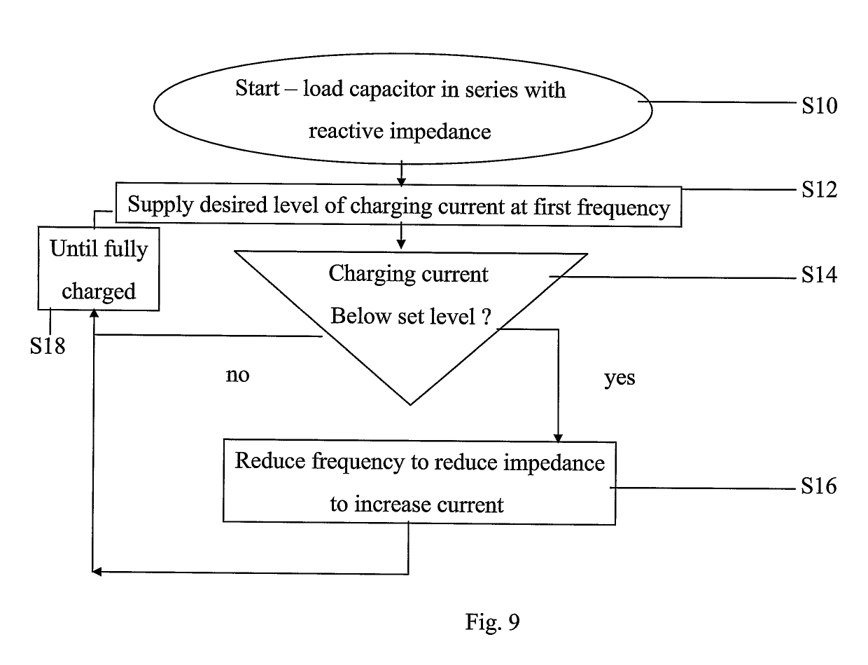

Reference is now made to FIG. 9, which is a simplified flow chart illustrating the operation of the circuit of FIG. 8. The method comprises providing constant current charging of a capacitive load, and comprises a first stage S10 of arranging the capacitive load in series with a reactive impedance comprising an inductive element and a capacitive element. In following stage S12, charging current is provided at a desired level at a controllable supply frequency. During charging, the charging current is measured and in a stage S14, when it is detected that the charging current begins to fall, the measured changes in the charging current are used to alter the supply frequency. More particularly, in a stage S16, measured changes in the charging current control the supply frequency. Changes in the supply frequency cause changes in the reactive impedance, and specifically, a reduction in the supply frequency causes a reduction in the impedance so that the fall in the supply current is compensated for. Consequently the charging current can be kept substantially constant throughout the time in which the capacitive load is charged. Once the capacitive load is fully charged then the current supply may be stopped S18.

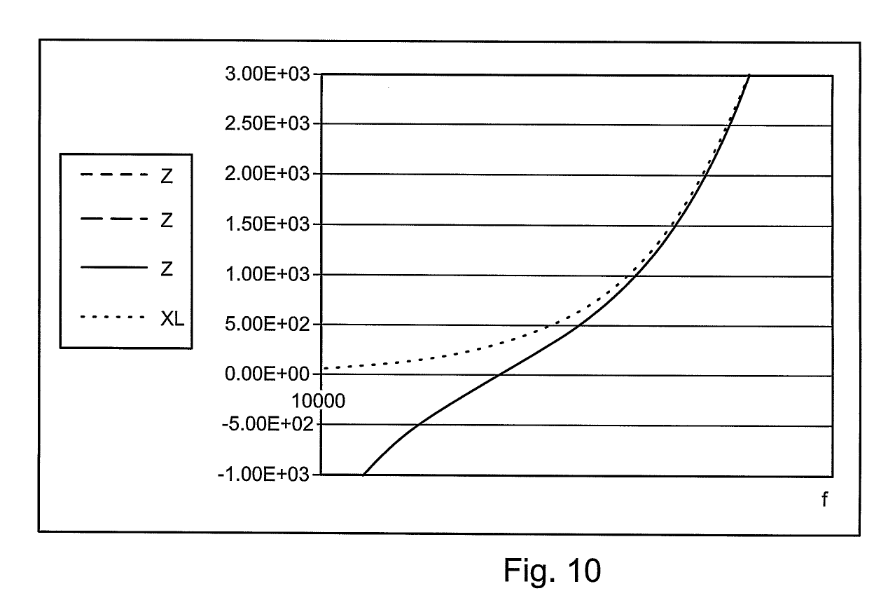

Reference is now made to FIG. 10, which is a graph illustrating the impedance against frequency characteristic for a circuit according to a preferred embodiment of the present invention. From the graph it is clear that as the frequency increases, so does the impedance, and as a consequence it may be appreciated that the current falls. Thus, in order to maintain the current it is necessary to decrease the frequency.

It is expected that during the life of this patent many relevant devices and systems will be developed and the scopes of the terms herein, particularly of the terms “signal generator”, “voltage source”, “transistor” “frequency modulation”, “pulse width modulation” and “FET”, are intended to include all such new technologies a priori.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims. All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention.

1. A high speed power supply arrangement suitable for laser diodes, comprising:
a) a variable voltage power supply,
b) a load path for carrying a laser diode,
c) a shunt path connected in parallel with said load path,
d) a current draining element for switching said shunt path, said current draining element being associated via a first feedback element with said variable voltage power supply such that current drained by said current draining element provides first feedback control of a voltage level of said variable voltage power supply, and
c) a voltage operated second feedback element associated with both said load path and said shunt path to provide second feedback control of said current draining element to drain current via said current draining element in response to current changes at said load, said voltage operated second feedback element thereby working together with said current draining element to provide current regulation of said load path from said shunt path.

2. The arrangement of claim 1, wherein said first feedback control is relatively slow and said second feedback control is faster than said relatively slow first feedback control.

3. The arrangement of claim 1, wherein said first feedback control is set with a response rate suitable for a DC-DC voltage level converter.

4. The arrangement of claim 1, wherein said second feedback control is set with a response rate in the microsecond order of magnitude.

5. The arrangement of claim 1, wherein said current draining element is a transistor.

6. A method of current regulation to provide constant current to a load comprising:
providing a power source having a controllable output voltage level, providing current to said load from said voltage power source,
connecting a current draining element in parallel with said load, and arranging:
relatively fast feedback control from said load to operate said current draining element to drain over current from said load, and
relatively slow feedback control responsive to current drained by said current draining element to control said output voltage level of said power source said relatively slow feedback control working together with said relatively fast feedback control to provide current regulation of a path of said load from a path shunting said load.

7. A circuit arrangement for charging a capacitance comprising:
a load capacitance to be charged,
a serially connected inductive component contributing to a serial frequency dependent impedance,
a variable frequency source for supplying charging current at a variable frequency, and
a current measurement device for measuring said charging current and using said measurement to provide a feedback signal to said variable frequency source, thereby to control said variable frequency to reduce said frequency,
said variable frequency source being controllable to reduce frequency during charging of said capacitor, thereby to reduce said frequency dependent impedance and maintain a level of charging current to said load capacitance.

8. The circuit arrangement of claim 7, further comprising a serially connected capacitive component to contribute to said serial frequency dependent impedance.

9. (canceled)

10. The circuit arrangement of claim 7, wherein said variable frequency source comprises pulse width modulation.

11. The circuit arrangement of claim 7, wherein said load capacitance is connected to said serial component via a rectifying bridge.

12. The circuit arrangement of claim 7, wherein said feedback signal is modified to stabilize said charging current at a constant level whilst said load capacitance is charging.

13. A method of providing constant current charging of a capacitive load comprising:
arranging said capacitive load in series with a reactive impedance comprising at least an inductive element,
providing current at a controllable supply frequency,
measuring an actual charging current of said capacitive load,
using measured changes in said charging current to control said frequency thereby to adjust said reactive impedance so as to keep said charging current substantially constant.

14. The method of claim 13, wherein said reactive impedance further comprises a capacitive element in series with said inductive element.

15. The method of claim 13, comprising arranging said capacitive load with a rectifying bridge so that said capacitive load receives substantially DC charging current irrespective of said supply frequency.
